(19) United States
(12) Patent Application Publication
(10) Pub. No.: US 2026/0242940 A1
(43) Pub. Date: Aug. 20, 2026

(54) FILM FORMATION METHOD AND FILM FORMATION APPARATUS

(71) Applicant: Tokyo Electron Limited, Tokyo (JP)

(72) Inventors: Yoshimasa WATANABE, Nirasaki City (JP); Kota UMEZAWA, Nirasaki City (JP); Katsutoshi ISHII, Tokyo (JP)

(21) Appl. No.: 19/642,856

(22) Filed: Apr. 9, 2026

Related U.S. Application Data
(63) Continuation of application No. PCT/JP2024/034906, filed on Sep. 30, 2024.

(30) Foreign Application Priority Data
Oct. 12, 2023 (JP) 2023-176352

(51) Int. Cl. C23C 16/40; C23C 16/44; C23C 16/455; C23C 16/46; C23C 16/52

(52) U.S. Cl. CPC C23C 16/401; C23C 16/4408; C23C 16/45536; C23C 16/46; C23C 16/52

(57) ABSTRACT

A film formation method of forming a film containing Si and O on a substrate, includes: supplying a Si-containing compound gas having a structural Formula (1) below to the substrate; and supplying an OH-containing gas to the substrate. The supplying the Si-containing compound gas and the supplying the OH-containing gas are alternately performed. R¹ is a hydrogen atom, a linear or branched alkyl group having 1 to 4 carbon atoms, a linear or branched alkoxy group having 1 to 4 carbon atoms, a linear or branched alkylthio group having 1 to 4 carbon atoms, or an aryl group having 6 to 12 carbon atoms. Ring R² is a heterocyclic ring containing a nitrogen atom, m is an integer of 1 to 5, n is an integer of 1 to 4, and the ring R² is a 3- to 6-membered ring.

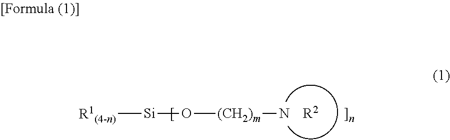

### CROSS-REFERENCE TO RELATED APPLICATIONS

The application is a Bypass Continuation Application of PCT International Application No. PCT/JP2024/034906, filed on Sep. 30, 2024 and designating the United States, the international application being based upon and claiming the benefit of priority from Japanese Patent Application No. 2023-176352, filed on Oct. 12, 2023, the entire contents of which are incorporated herein by reference.

### TECHNICAL FIELD

The present disclosure relates to a film formation method and a film formation apparatus.

### BACKGROUND

In a process of manufacturing a semiconductor device, a film containing Si and O, such as a silicon oxide film, is widely used as an insulating film. In forming the silicon oxide film, low-temperature film formation is desired, and Patent Document 1 describes a technique for forming a silicon oxide film at a low temperature of 200 degrees C. or less by atomic layer deposition (ALD) in which diisopropylamino silane serving as a silicon raw material and an activated oxidant such as oxygen plasma or ozone are alternately supplied.

### PRIOR ART DOCUMENTS

### Patent Documents

Patent Document 1: Japanese Patent Laid-open Publication No. 2009-206500

### SUMMARY

According to one embodiment of the present disclosure, a method of forming a film containing Si and O on a substrate, includes supplying a Si-containing compound gas having a structural Formula (1) below as a Si source gas to the substrate and supplying an OH-containing gas as a reaction gas to the substrate. The supplying the Si-containing compound gas and the supplying the OH-containing gas are alternately performed.

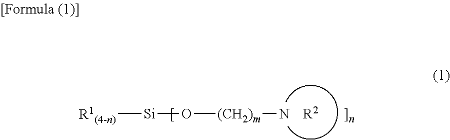

R¹ is a hydrogen atom, a linear or branched alkyl group having 1 to 4 carbon atoms, a linear or branched alkoxy group having 1 to 4 carbon atoms, a linear or branched alkylthio group having 1 to 4 carbon atoms, or an aryl group having 6 to 12 carbon atoms. Ring R² is a heterocyclic ring containing a nitrogen atom, m is an integer of 1 to 5, n is an integer of 1 to 4, and the ring R² is a 3- to 6-membered ring.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating an exemplary film formation method according to an embodiment.

FIGS. 2A to 2C are diagrams illustrating a reaction model when a film formation method according to an embodiment is performed.

FIG. 3 is a diagram illustrating a relationship between substrate temperature and cycle rate when a film is formed by a thermal reaction using a Si-containing compound gas of Formula (2) and using H₂O gas as an OH-containing gas.

FIG. 4 is a diagram illustrating a relationship between substrate temperature and cycle rate when a film is formed using the Si-containing compound gas of Formula (2) and using plasma H₂O as a reaction gas.

FIG. 5 is a diagram illustrating XPS peaks of WO₃ and W when an SiO₂ film is formed using the Si-containing compound gas of Formula (2) and plasma O₂ on a substrate sample having a W film on a surface of the substrate sample.

FIG. 6 is a diagram illustrating XPS peaks of WO₃ and W when an SiO₂ film is formed by a thermal reaction using the Si-containing compound gas of Formula (2) and H₂O gas on a substrate sample having a W film on a surface of the substrate sample.

FIG. 7 is a diagram illustrating results of measuring nitrogen (N) concentration in films by SIMS with respect to an SiO₂ film formed using the Si-containing compound gas of Formula (2) and plasma H₂O, and an SiO₂ film formed by a thermal reaction using the Si-containing compound gas of Formula (2) and H₂O gas.

FIG. 8 is a cross-sectional view illustrating an exemplary film formation apparatus capable of performing a film formation method according to an embodiment.

FIG. 9 is a cross-sectional view illustrating another exemplary film formation apparatus capable of performing a film formation method according to an embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments will be described with reference to the accompanying drawings.

### Background and Overview

First, the background and overview will now be described.

In a process of manufacturing a semiconductor device, Atomic Layer Deposition (ALD) in which a silicon source gas and a reactive gas (oxidant) are alternately supplied has been used to form a film containing Si and O, such as a silicon oxide (SiO₂) film, used as an insulating layer. In forming the silicon oxide film, low-temperature film formation is desired, and Patent Document 1 describes a technique for forming the SiO₂ film at a low temperature of 200 degrees C. or less by alternately supplying diisopropylamino silane serving as a silicon raw material and an activated oxidant such as oxygen plasma or ozone.

However, in recent years, semiconductor devices become more miniaturized and complex, and various excellent film formation characteristics are required in addition to the low-temperature film formation aimed at in Patent Document 1. For example, it is required that oxidation damage to an underlying layer be small or a film be formed with high step coverage in a fine recess formed on a substrate surface. In this regard, when the activated oxygen such as oxygen plasma or ozone is used as the oxidant as in Patent Document 1, there is a concern that oxidation damage to the underlying layer may occur and that step coverage in the recess formed in the substrate may be insufficient. In addition, as the film formation characteristics, it is sometimes required that a film contain fewer impurities.

Therefore, in the present embodiment, in forming a film containing Si and O by ALD in which supplying an Si source gas to a substrate and supplying a reaction gas to the substrate are alternately performed, an Si-containing compound gas having a structural Formula (1) below is used as the Si source gas, and an OH-containing gas is used as the reaction gas.

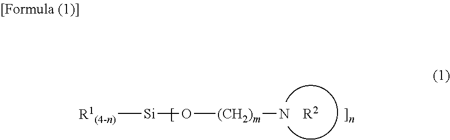

Here, R¹ is a hydrogen atom, a linear or branched alkyl group having 1 to 4 carbon atoms, a linear or branched alkoxy group having 1 to 4 carbon atoms, a linear or branched alkylthio group having 1 to 4 carbon atoms, or an aryl group having 6 to 12 carbon atoms.

Ring R² is a heterocyclic ring containing a nitrogen atom, m is an integer of 1 to 5, n is an integer of 1 to 4, and the ring R² is desirably a 3- to 6-membered ring.

The Si-containing compound is a novel compound, and a portion including the ring R² can be terminated by OH and eliminated by the OH-containing gas, such as H₂O or H₂O₂. This reaction can proceed with low energy, thereby enabling low-temperature film formation. In addition, since the reaction can be carried out using the OH-containing gas, excellent film formation characteristics can be obtained.

### Specific Embodiment

A method of forming a film according to an embodiment forms a film containing Si and O, for example, an SiO₂ film, by ALD in which supplying an Si source gas and supplying an oxidizing gas are alternately performed in a state in which a substrate is disposed in a chamber of a film formation apparatus.

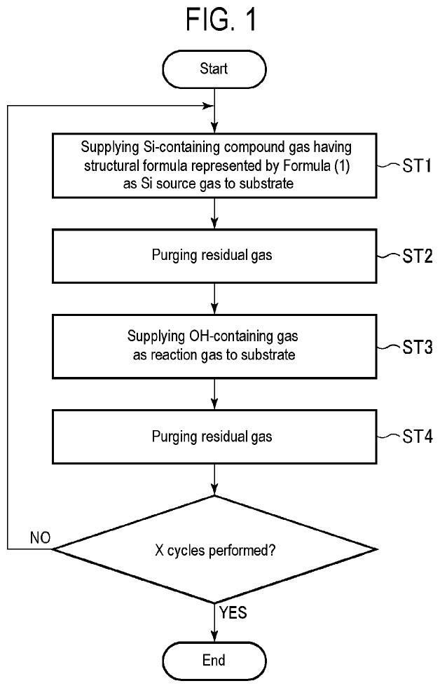

More specifically, for example, as shown in the flowchart of FIG. 1, step ST1, step ST2, step ST3, and step ST4 are performed for a desired number of cycles (X cycles). Step ST1 is a step of supplying the Si-containing compound gas of the above structural Formula (1) as a Si source gas to a substrate. Step ST2 is a step of purging a residual gas after performing step ST1. Step ST3 is a step of supplying an OH-containing gas as a reaction gas to the substrate. Step ST4 is a step of purging a residual gas after performing step ST3.

Although the substrate is not particularly limited, a semiconductor substrate is exemplified. A typical example of the semiconductor substrate is an Si substrate. In this case, the substrate may be composed only of Si or may have a metal-based film such as a tungsten (W) film formed on an Si base. That is, the surface of the substrate may be Si or a metal. Examples of the metal-based film include, in addition to the W film, a titanium nitride (TiN) film or a copper (Cu) film. The substrate may also have a recess, such as a trench or a hole, on a surface on which a film is to be formed.

In step ST1, as described above, the Si-containing compound gas having the structural Formula (1) is supplied to the substrate as the Si source gas so as to be adsorbed onto the substrate. The time of step ST1 and the flow rate of the Si source gas are appropriately determined so that a desired amount of the Si-containing compound gas is adsorbed onto the substrate.

In Formula (1), the alkyl group constituting R¹ includes, for example, a methyl group, an ethyl group, and a propyl group, and the alkoxy group includes, for example, a methoxy group, an ethoxy group, a propoxy group, and an isopropoxy group. The alkylthio group includes, for example, a methylthio group, an ethylthio group, a propylthio group, and an isopropylthio group, and the aryl group includes, for example, a phenyl group, a toluyl group, a xylyl group, and a naphthyl group. The ring R², which is a nitrogen-containing heterocyclic ring, may be a 3- to 6-membered ring as described above and may be a saturated heterocyclic ring or an unsaturated heterocyclic ring. The ring R² may have a substituent. Examples of the substituent include an alkyl group, an alkoxy group, a thioethyl group, an aryl group, an amino group, an acetyl group, a benzoyl group, a carboxyl group, a carboxylic acid ester group, and a cyano group. The ring R² includes, for example, pyrrolidine, which is a 5-membered ring. A specific example of the compound is N-[2-(trimethoxysilyloxy)ethyl]pyrrolidine having a structural Formula (2) below.

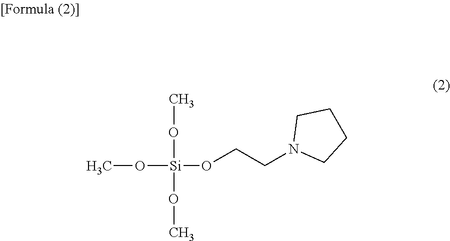

In step ST2, the purge gas is supplied to the chamber after performing step ST1 to purge the residual gas remaining inside the chamber. The purge gas may be an inert gas. As the inert gas, a noble gas, such as Ar gas or He gas, or N₂ gas can be suitably used. The time of step ST2 and the flow rate of the purge gas are appropriately determined so that the residual gas remaining in the chamber is sufficiently discharged.

In step ST3, as described above, the OH-containing gas, for example, H₂O gas or H₂O₂ gas, is supplied to the substrate as the reaction gas. As a result, the OH-containing gas reacts with the Si-containing compound gas adsorbed onto the substrate, and a film containing Si and O is formed as a thin film at a molecular layer level. The OH-containing gas, which is the reaction gas, can react with the Si-containing compound gas by a thermal reaction. However, the OH-containing gas may also be plasma. The time of step ST3 and the flow rate of the OH-containing gas are appropriately determined so that the reaction with the Si-containing compound gas adsorbed onto the substrate sufficiently occurs.

In step ST4, the purge gas is supplied to the chamber after performing step ST3 to purge the residual gas remaining inside the chamber. As in step ST2, the purge gas may be an inert gas. The time of step ST4 and the flow rate of the purge gas are appropriately determined so that the residual gas remaining inside the chamber is sufficiently discharged.

By performing step ST1 to step ST4 for a desired number of cycles (X cycles), the film containing Si and O having a desired film thickness is formed. The film containing Si and O may be, in addition to the above-described SiO₂ film, an SiOCN film. The SiOCN film can be formed, for example, by intentionally incorporating N or C into the film from the Si-containing compound gas by using a technique such as lowering substrate temperature during film formation.

In addition, during the step ST1 to step ST4, the substrate temperature (film formation temperature) may be in a range of 20 degrees C. to 400 degrees C., and the pressure may be in a range of 1 Torr to 100 Torr (133 Pa to 13,300 Pa).

In the present embodiment, a reaction as Formula (3) below can be generated using the Si-containing compound gas of Formula (1) as the Si source gas and using the OH-containing gas, for example, H₂O gas, as the reaction gas. In addition, Formula (4) below represents a specific reaction in the case in which the Si-containing compound is the compound of Formula (2).

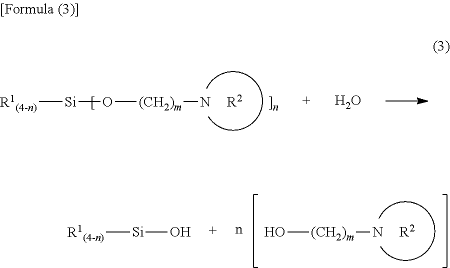

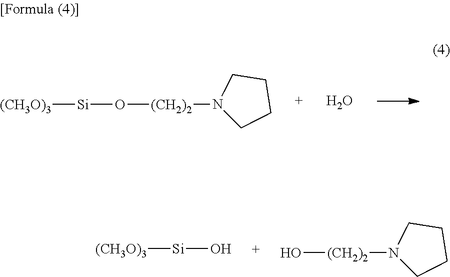

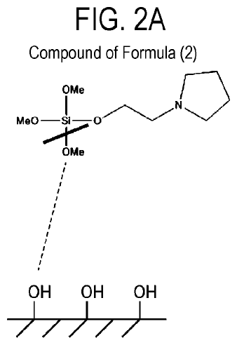

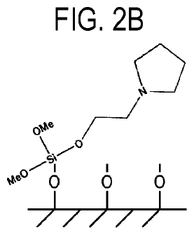

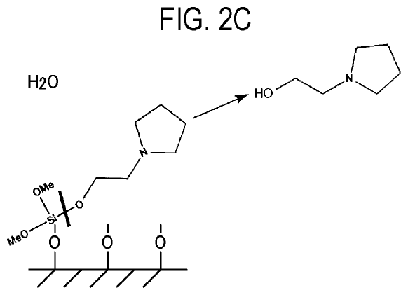

A reaction model in this case is shown in FIGS. 2A to 2C. FIGS. 2A to 2C illustrate, as an example, a case in which the compound gas of Formula (2) is used as the Si-containing compound of Formula (1) and H₂O gas is used as the OH-containing gas. First, as shown in FIG. 2A, the Si-containing compound gas of Formula (2) is supplied to the substrate. As a result, as shown in FIG. 2B, the Si-containing compound gas of Formula (2) is adsorbed onto the substrate. In this state, by supplying the H₂O gas as the reaction gas, a portion including the ring R² is terminated by OH and subsequently eliminated, as shown in FIG. 2C.

As described above, in the present embodiment, the film formation reaction between the Si-containing compound of Formula (1) and the OH-containing gas causes a large molecule including the ring R² to be eliminated from the Si-containing compound of Formula (1). Therefore, the reaction readily proceeds, and the film formation reaction can be carried out with low energy, thereby enabling low-temperature film formation. In the case of the thermal reaction, a higher film formation rate can be obtained at a substrate temperature of 100 degrees C. or less.

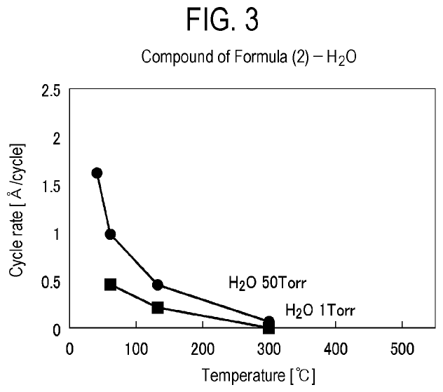

FIG. 3 is a diagram illustrating the relationship between substrate temperature (film formation temperature) and cycle rate (film formation rate per one cycle) when a film is formed by a thermal reaction using a compound gas of Formula (2) as the Si-containing compound gas of Formula (1) and using H₂O gas as the OH-containing gas. The diagram shows cases in which H₂O pressure is set to 1 Torr and 50 Torr. As shown in this figure, when the temperature is 300 degrees C. or higher, the film formation rate is low, whereas favorable film formation is achieved at a low temperature of 200 degrees C. or lower, and in particular, a high film formation rate is obtained at 100 degrees C. or lower. Regarding the H₂O pressure, the film formation rate tends to be higher at 50 Torr than at 1 Torr.

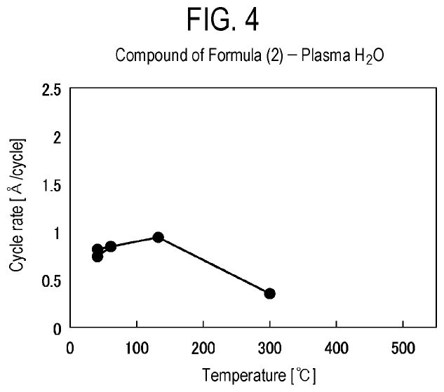

FIG. 4 is a diagram illustrating the relationship between substrate temperature and cycle rate when a film is formed using the compound gas of Formula (2) as the Si-containing compound of Formula (1) and using plasma H₂O as the reaction gas. As shown in this figure, even when plasma H₂O is used, it can be seen that film formation is possible at a low temperature, and a high film formation rate (cycle rate) is obtained at a temperature of about 100 degrees C. or lower.

By forming the film containing Si and O using the Si-containing compound gas of Formula (1) as the Si source gas and the OH-containing gas as the reaction gas as described above, it is possible not only to perform low-temperature film formation but also to obtain excellent film formation characteristics as follows.

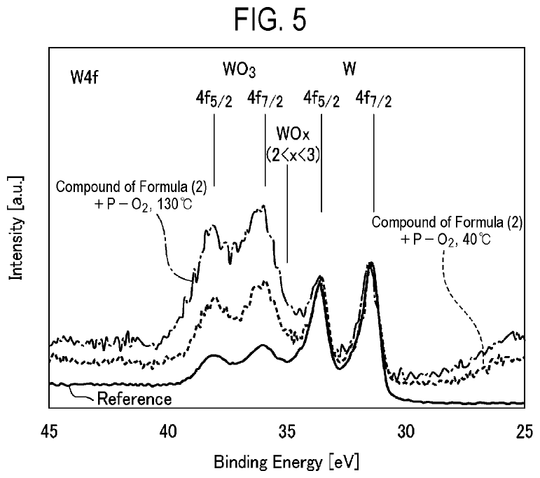

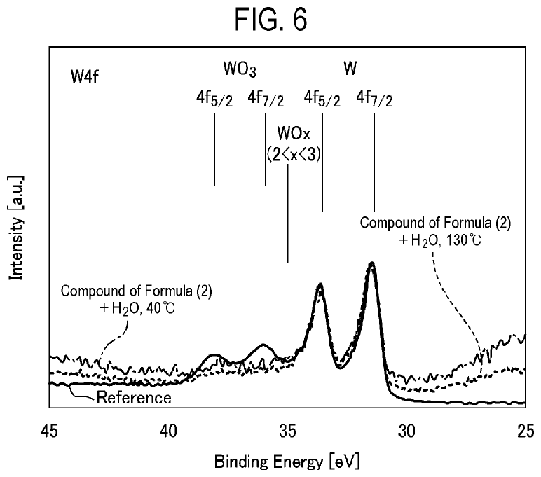

The OH-containing gas, such as H₂O gas or H₂O₂ gas used as the reaction gas, has weaker oxidizing power than oxygen gas, oxygen plasma, or ozone. Therefore, when a film is formed by a thermal reaction using the Si-containing compound gas of Formula (1) and the OH-containing gas, not only can the film formation temperature be reduced, but also oxidation damage to an underlying layer can be suppressed. This is also clear from XPS peaks shown in FIGS. 5 and 6.

FIG. 5 is a diagram illustrating XPS peaks of WO₃ and W when an SiO₂ film is formed using the compound gas of Formula (2) and plasma O₂ on a substrate sample having a W film on the surface thereof. FIG. 6 is a diagram illustrating XPS peaks of WO₃ and W when an SiO₂ film is formed by a thermal reaction using the compound gas of Formula (2) and H₂O gas on the substrate sample having the W film on the surface thereof. Here, the substrate samples were prepared by forming W film having a thickness of 100 nm formed on Si bases by sputtering and then removing native oxide films on surfaces using dilute hydrofluoric acid (DHF). Subsequently, SiO₂ films having a thickness of 10 nm were formed at 40 degrees C. and 130 degrees C. by respective film formation methods. FIGS. 5 and 6 also show, as references, results of the W films on which the native oxide films were formed.

In the case in which the film was formed using the compound gas of Formula (2) and the plasma O₂, as shown in FIG. 5, it was confirmed that an oxide film having a higher oxidation level than a native oxide film was formed at the interface of the W film. In the case in which the film was formed by the thermal reaction using the compound gas of Formula (2) and the H₂O gas, as shown in FIG. 6, it was confirmed that oxidation was suppressed to a level below the native oxide film.

In the present embodiment, by applying the formation of the film containing Si and O by the thermal reaction using the Si-containing compound of Formula (1) and the OH-containing gas to a substrate having a fine, high-aspect-ratio recess on the surface, film formation characteristics such as high step coverage can be achieved. That is, when forming a film on the substrate having the fine, high-aspect-ratio recess, there is a concern that an excited oxidant such as oxygen plasma or ozone may be deactivated at the bottom of the recess, whereas in a thermal reaction, the OH-containing gas can reach the bottom of the recess while maintaining reactivity. Therefore, by the thermal reaction using the OH-containing gas, a reduction in step coverage, which is a concern when using the excited oxidant, is suppressed, and high step coverage can be obtained.

On the other hand, when plasma of the OH-containing gas is used as the reaction gas, the reaction proceeds by OH radicals (OH*). Therefore, the oxidizing power with respect to an underlying layer is stronger than in the case of the thermal reaction, and there is also a concern that deactivation may occur at the bottom of the recess. For this reason, when plasma is used, the effects of suppressing oxidation of the underlying layer and suppressing a reduction in step coverage are smaller than in the case of the thermal reaction. However, by using plasma as the reaction gas, other excellent film formation characteristics, such as low impurity concentration in the formed film, can be obtained.

That is, in the present embodiment, as described in the model shown in FIGS. 2A to 2C above, the film formation reaction proceeds by elimination of the large molecule including the ring R² from the Si-containing compound of Formula (1) through a reaction between the Si-containing compound of Formula (1) and the OH-containing gas such as H₂O. Since a product after elimination has been terminated by OH, the product is unlikely to be introduced into the film once eliminated. In the thermal reaction, however, there is a concern that molecules including the ring R² may not be sufficiently eliminated and may remain as impurities in the film. In contrast, by using plasma of the OH-containing gas, the reactivity is increased, thereby promoting elimination of the large molecule including the ring R² and reducing impurity concentration in the film, particularly, N concentration. When forming the SiO₂ film as the film containing Si and O, it is important that the N concentration as an impurity be low, and in this respect, using plasma of the OH-containing gas as the reaction gas is effective.

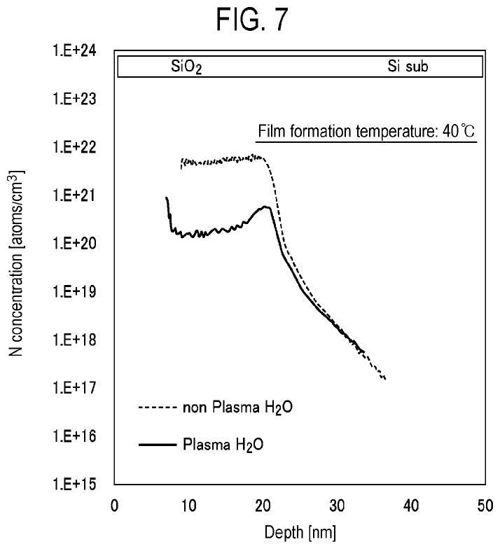

FIG. 7 illustrates results of measuring N concentration in films by SIMS for an SiO₂ film formed by using a compound gas of Formula (2), which is example of the Si-containing compound gas of Formula (1), and plasma H₂O and an SiO₂ film formed by a thermal reaction using the compound gas of Formula (2) and non-plasma H₂O gas. The substrate temperature was set to 40 degrees C. As shown in FIG. 7, it can be seen that, by using plasma H₂O, the N concentration can be reduced to about 1/30 compared with the case of the thermal reaction. Although FIG. 7 shows values at a substrate temperature of 40 degrees C., the N concentration in the film varies depending on the substrate temperature, and the N concentration can be reduced by increasing the substrate temperature.

### <Film Formation Apparatus>

Next, an example of a film formation apparatus applicable to implementation of the above-described film formation method will be described.

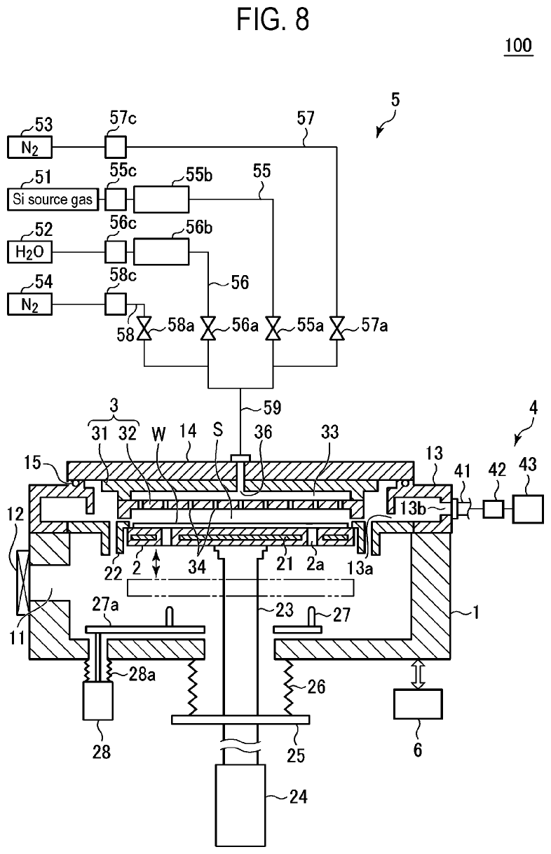

FIG. 8 is a cross-sectional view illustrating an example of a film formation apparatus.

A film formation apparatus 100 has a chamber 1, a stage 2, a shower head 3, an exhauster 4, a gas supply mechanism 5, and a controller 6. The film formation apparatus 100 forms an SiO₂ film, which is a film containing Si and O, on a substrate W. The substrate W is not particularly limited and may be a semiconductor substrate. An example of the semiconductor substrate includes a substrate in which a metal-based film is formed on a semiconductor base such as Si.

The chamber 1 is made of a metal such as aluminum and has a substantially cylindrical shape. A loading/unloading port 11 for loading/unloading the substrate W is formed in a side wall of the chamber 1 and is configured to be opened/closed by a gate valve 12. An annular exhaust duct 13 having a rectangular cross section is provided on a main body of the chamber 1. A slit 13a is formed along an inner peripheral surface of the exhaust duct 13. An exhaust port 13b is formed in an outer wall of the exhaust duct 13. A ceiling wall 14 is provided on an upper surface of the exhaust duct 13 so as to close an upper opening of the chamber 1. A space between the ceiling wall 14 and the exhaust duct 13 is hermetically sealed by a seal ring 15.

The stage 2 is to place the substrate W in a horizontal state, is formed in a disc shape of a size corresponding to the substrate W, and is supported by a support 23. The stage 2 is made of a ceramic material such as aluminum nitride (AlN) or a metal material such as aluminum or a nickel-based alloy, and a heater 21 for heating the substrate W is embedded in the stage 2. The stage 2 is provided with a cover 22 to cover a side surface of the stage 2. By controlling the output of the heater 21, the temperature of the substrate W on the stage 2 is controlled to a desired temperature within a range of, for example, 20 degrees C. to 400 degrees C.

The support 23 supporting the stage 2 extends below the chamber 1 from the center of a bottom surface of the stage 2 by passing through a hole formed in a bottom wall of the chamber 1 and a lower end of the support 23 is connected to a stage lifting mechanism 24. The stage 2 is configured to move vertically by the stage lifting mechanism 24 via the support 23 between a processing position indicated by a solid line and a transfer position below the processing position, indicated by a dash-dotted line, at which the substrate can be transferred. A flange 25 is installed on the support 23 at a position below the chamber 1, and a bellows 26 that partitions an atmosphere inside the chamber 1 from an outside air and expands/contracts according to a raising/lowering operation of the stage 2 is provided between a bottom surface of the chamber 1 and the flange 25.

Three substrate support pins 27 (only two of which are shown) are provided in a vicinity of the bottom surface of the chamber 1 to protrude upward from a lifting plate 27a. The substrate support pins 27 are configured so as to be raised/lowered via the lifting plate 27a by a substrate support pin lifting mechanism 28 provided below the chamber 1 and are configured so as to protrude/retract with respect to an upper surface of the stage 2 by being inserted into through-holes 2a provided in the stage 2 located at the transfer position. By raising/lowering the substrate support pins 27 in this way, the substrate W is delivered between a substrate transfer mechanism (not shown) and the stage 2. A bellows 28a is provided between the bottom surface of the chamber 1 and the substrate support pin lifting mechanism 28.

The shower head 3 supplies a processing gas into the chamber 1 in a shower form. The shower head 3 is provided to face the stage 2 and has almost the same diameter as the diameter of the stage 2. The shower head 3 has a shower body 31 fixed to the ceiling wall 14 of the chamber 1 and a shower plate 32 connected below the shower body 31. A gas diffusion space 33 is formed between the shower body 31 and the shower plate 32. A gas introduction hole 36 provided to penetrate the center of the shower body 31 and the ceiling wall 14 of the chamber 1 is connected to the gas diffusion space 33. Gas ejection holes 34 are formed in the shower plate 32. When the stage 2 is at the processing position, a processing space S is formed between the shower plate 32 and the stage 2.

The exhauster 4 is provided with an exhaust pipe 41 connected to the exhaust port 13b of the exhaust duct 13, an automatic pressure control (APC) valve 42 connected to the exhaust pipe 41, and an exhaust mechanism 43 having a vacuum pump. During processing, gas in the chamber 1 reaches the exhaust duct 13 via the slit 13a and is exhausted from the exhaust duct 13 via the exhaust pipe 41 by the exhaust mechanism 43 of the exhauster 4.

The gas supply mechanism 5 supplies gases used for film formation to the shower head 3 and supplies a Si source gas, a reaction gas, and a purge gas. Here, an example is shown in which the compound gas of Formula (2), which is an example of the Si-containing compound gas of Formula (1), is used as the Si source gas, H₂O gas, which is an example of the OH-containing gas, is used as the reaction gas, and N₂ gas is used as the purge gas.

The gas supply mechanism 5 has a Si-containing compound gas supply source 51 that supplies the compound gas of Formula (2) as the Si source gas, an H₂O gas supply source 52 that supplies H₂O gas as the reaction gas, and a first N₂ gas supply source 53 and a second N₂ gas supply source 54 that supply N₂ gas as the purge gas.

One end of a Si-containing compound gas line 55 is connected to the Si-containing compound gas supply source 51, and a valve 55a, a fill tank 55b, and a flow rate adjuster 55c are interposed in the Si-containing compound gas line 55 in this order from a downstream. One end of an H₂O gas line 56 is connected to the H₂O gas supply source 52, and a valve 56a, a fill tank 56b, and a flow rate adjuster 56c are interposed in the H₂O gas line 56 in this order from a downstream. The Si-containing compound gas line 55 and the H₂O gas line 56 are connected to one end of a common line 59, and the other end of the common line 59 is connected to the gas introduction hole 36 of the shower head 3.

One end of a first N₂ gas line 57 is connected to the first N₂ gas supply source 53, and a valve 57a and a flow rate adjuster 57c are interposed in the first N₂ gas line 57 in this order from a downstream. The other end of the first N₂ gas line 57 is connected to a downstream of the valve 55a of the Si-containing compound gas line 55. One end of a second N₂ gas line 58 is connected to the second N₂ gas supply source 54, and a valve 58a and a flow rate adjuster 58c are interposed in the second N₂ gas line 58 in this order from a downstream. The other end of the second N₂ gas line 58 is connected to a downstream of the valve 56a of the H₂O gas line 56. During the film formation process, the valves 57a and 58a are constantly open, and N₂ gas as the purge gas is constantly supplied into the chamber 1 from the first N₂ gas line 57 and the second N₂ gas line 58 via the Si-containing compound gas line 55 and the H₂O gas line 56.

The valves 55a and 56a are configured as high-speed opening/closing valves that open and close corresponding gas lines at high speed. The valves 57a and 58a are normal opening/closing valves.

The fill tanks 55b and 56b temporarily store the compound gas of Formula (2) and the H₂O gas, respectively, before supplying the gases into the chamber 1. By storing the gases in the fill tanks 55b and 56b, pressure inside the fill tanks 55b and 56b is increased to a predetermined pressure, and then each gas may be discharged into the chamber 1 by opening the valves 55a and 56a. This allows a large flow rate of gas to be stably supplied to the chamber 1. In addition, the fill tanks 55b and 56b are not essential. A carrier gas supply source may be provided to an upstream of the Si-containing compound gas supply source 51 and the H₂O gas supply source 52. The Si-containing compound gas or the H₂O gas can be supplied stably and efficiently by using a carrier gas. As the carrier gas, N₂ gas or a noble gas such as Ar gas can be used.

The flow rate adjusters 55c, 56c, 57c, and 58c are configured, for example, by mass flow controllers and adjust/control flow rates of gases flowing through the corresponding gas lines.

The controller 6 is configured as a computer and has a main controller including a CPU, an input device, an output device, a display device, and a storage device (non-transitory computer-readable storage medium). The main controller controls components of the film formation apparatus 100, for example, the valves, the flow rate adjusters, the APC valve, the heater, and the lifting mechanism. In the storage device, parameters for various processes executed in the film formation apparatus 100 are stored. In addition, the storage device has a non-transitory computer-readable storage medium in which programs for controlling the processes to be executed in the film formation apparatus 100, i.e., process recipes, are stored. The main controller calls a predetermined process recipe which is stored in the storage medium and causes the film formation apparatus 100 to perform a predetermined process based on the process recipe.

In the film formation apparatus 100 configured in this way, first, the gate valve 12 is opened, and the substrate W is loaded into the chamber 1 through the loading/unloading port 11 by a transfer device (not shown) and placed on the stage 2. The transfer device is retracted, and the stage 2 is raised to the processing position. Then, the gate valve 12 is closed to evacuate the interior of the chamber 1. While the valves 57a and 58a are opened to supply N₂ gas as the purge gas into the processing space S from the first N₂ gas supply source 53 and the second N₂ gas supply source 54 via the first N₂ gas line 57, the second N₂ gas line 58, and the shower head 3, the temperature of the stage 2 (substrate temperature) is heated and controlled to a desired temperature by the heater 21.

In a state in which the N₂ gas as the purge gas is being supplied from the first N₂ gas supply source 53 and the second N₂ gas supply source 54, the valve 55a is opened, and the compound gas of Formula (2) is supplied as the Si source gas into the processing space S from the Si-containing compound gas supply source 51 via the Si-containing compound gas line 55 and the shower head 3 (step ST1). As a result, the compound gas of Formula (2) is adsorbed onto the substrate W.

Subsequently, in a state in which the N₂ gas as the purge gas continues to be supplied, the valve 55a is closed to stop the supply of the compound gas of Formula (2), and residual gas remaining inside the chamber 1 (processing space S) is purged (step ST2).

Next, in a state in which the N₂ gas as the purge gas is being supplied, the valve 56a is opened, and H₂O gas is supplied as the reaction gas into the processing space S from the H₂O gas supply source 52 via the H₂O gas line 56 and the shower head 3 (step ST3). As a result, the compound gas of Formula (2) adsorbed onto the substrate W reacts with the H₂O gas by a thermal reaction, thereby forming a thin SiO₂ film.

Subsequently, in a state in which the N₂ gas as the purge gas continues to be supplied, the valve 56a is closed to stop the supply of the H₂O gas, and residual gas remaining inside the chamber 1 (processing space S) is purged (step ST4).

By performing step ST1 to step ST4 for a desired number of cycles, an SiO₂ film having a desired thickness is formed.

After the formation of the above SiO₂ film is completed, the inside of the chamber 1 is purged by the N₂ gas, the gate valve 12 is opened, and the substrate Wis unloaded from the chamber 1 via the loading/unloading port 11 by the transfer device (not shown).

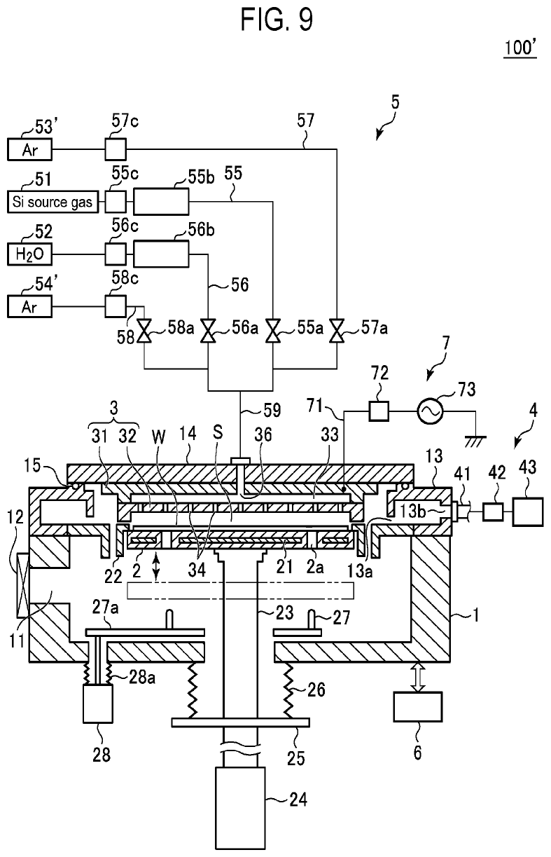

The film formation apparatus 100 of FIG. 8 forms the SiO₂ film by supplying H₂O gas using a thermal reaction. However, the H₂O gas may be excited by plasma. In that case, a film formation apparatus 100′ of FIG. 9 can be used. The film formation apparatus 100′ of FIG. 9 is obtained by adding a plasma generator 7 to the film formation apparatus 100. In addition, a first Ar gas supply source 53′ and a second Ar gas supply source 54′ are provided instead of the first N₂ gas supply source 53 and the second N₂ gas supply source 54 of the film formation apparatus 100 so that Ar gas, which also functions as a plasma generation gas, is supplied as the purge gas instead of the N₂ gas. Since the other configurations are the same as those of the film formation apparatus 100, the same components as those of the film formation apparatus 100 are denoted by the same reference numerals, and description thereof will be omitted. In addition, other noble gases may be used instead of the Ar gas.

The plasma generator 7 includes a power feed line 71 connected to the shower body 31 of the shower head 3, and a matcher 72 and a radio frequency (RF) power supply 73 connected to the power feed line 71. By supplying RF power from the RF power supply 73 to the shower head 3, an RF electric field is formed in the processing space S between the shower head 3 and the stage 2. Capacitively coupled plasma is generated in the processing space S by generating the RF electric field in a state in which the Ar gas and the H₂O gas are supplied to the processing space S. Furthermore, when the stage 2 is made of a ceramic material, an electrode is embedded in the stage 2 to form the RF electric field between the shower head 3 and the electrode.

In the film formation apparatus 100′ of FIG. 9, when performing step ST3 of supplying the H₂O gas as the reaction gas to the processing space S, the Ar gas, which also functions as the plasma generation gas, is supplied, and the RF power supply 73 is turned on to generate H₂O plasma in the processing space S. This enables the reaction between the compound gas of Formula (2) adsorbed on the substrate W and plasma H₂O.

### OTHER APPLICATIONS

While the embodiment has been described hereinabove, it is to be noted that the embodiment disclosed herein is exemplary in all respects and is not restrictive. The above-described embodiment may be omitted, replaced, and/or modified in various forms without departing from the scope and spirit of the appended claims.

For example, although single-wafer type apparatuses as shown in FIGS. 8 and 9 have been presented as the film formation apparatus in the above embodiment, these are merely examples, and the film formation apparatus is not particularly limited as long as the apparatus can form a film containing Si and O by ALD. For example, the apparatus is not limited to the single-wafer type and may be a batch-type apparatus. Furthermore, while the film formation apparatus in FIG. 9 shows an example of generating capacitively coupled plasma as plasma for exciting an OH-containing gas such as H₂O, the disclosure is not limited thereto, and various types of plasma, such as inductively coupled plasma or microwave plasma can be used. Alternatively, remote plasma, in which plasma generated at a different location is transferred to a substrate, may also be used.

According to the present disclosure in some embodiments, it is possible to provide a film formation method and a film formation apparatus capable of forming a film containing Si and O at a low temperature and with excellent film forming characteristics.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A film formation method of forming a film containing Si and O on a substrate, comprising:
supplying a Si-containing compound gas having a structural Formula (1) below as a Si source gas to the substrate; and
supplying an OH-containing gas as a reaction gas to the substrate, 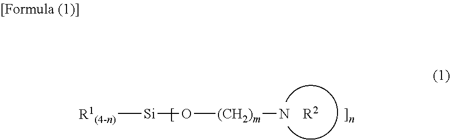
wherein the supplying the Si-containing compound gas and the supplying the OH-containing gas are alternately performed,
wherein R¹ is a hydrogen atom, a linear or branched alkyl group having 1 to 4 carbon atoms, a linear or branched alkoxy group having 1 to 4 carbon atoms, a linear or branched alkylthio group having 1 to 4 carbon atoms, or an aryl group having 6 to 12 carbon atoms,
wherein a ring R² is a heterocyclic ring containing a nitrogen atom,
wherein m is an integer of 1 to 5,
wherein n is an integer of 1 to 4, and
wherein the ring R² is a 3- to 6-membered ring.

2. The film formation method of claim 1, wherein the Si-containing compound gas is adsorbed onto the substrate by supplying the Si-containing compound gas, and
wherein the Si-containing compound gas on the substrate reacts with the OH-containing gas by supplying the OH-containing gas as the reaction gas to the substrate.

3. The film formation method of claim 2, wherein a reaction between the Si-containing compound gas on the substrate and the OH-containing gas is performed by a thermal reaction.

4. The film formation method of claim 3, wherein the substrate has a recess on a surface on which a film is to be formed.

5. The film formation method of claim 1, wherein the OH-containing gas supplied as the reaction gas is plasma.

6. The film formation method of claim 1, wherein the ring R² of the Si-containing compound gas is a five-membered ring.

7. The film formation method of claim 6, wherein the ring R² of the Si-containing compound gas is pyrrolidine.

8. The film formation method of claim 7, wherein the Si-containing compound gas is N-[2-(trimethoxysilyloxy)ethyl]pyrrolidine.

9. The film formation method of claim 8, wherein the substrate has a recess on a surface on which a film is to be formed.

10. The film formation method of claim 1, wherein the OH-containing gas is H₂O gas or H₂O₂ gas.

11. The film formation method of claim 1, wherein the substrate has a recess on a surface on which a film is to be formed.

12. The film formation method of claim 1, wherein a surface of the substrate is a surface containing Si or a metal.

13. The film formation method of claim 1, wherein the film containing Si and O is an SiO₂ film.

14. The film formation method of claim 1, further comprising:
purging a residual gas after the supplying the Si-containing compound gas; and
purging a residual gas after the supplying the OH-containing gas.

15. A film formation apparatus, comprising:
a chamber in which a substrate is accommodated;
a gas supply mechanism configured to supply gases including a Si source gas and a reaction gas into the chamber;
an exhaust mechanism configured to evacuate an interior of the chamber;
a heater configured to heat the substrate; and
a controller,
wherein the controller is configured to form a film containing Si and O on the substrate by alternately performing:
supplying a Si-containing compound gas having a structural Formula (1) below as the Si source gas to the substrate accommodated in the chamber; and
supplying an OH-containing gas as the reaction gas to the substrate, 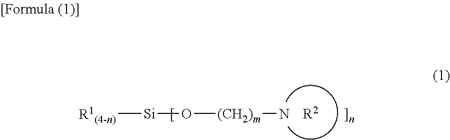
wherein R¹ is a hydrogen atom, a linear or branched alkyl group having 1 to 4 carbon atoms, a linear or branched alkoxy group having 1 to 4 carbon atoms, a linear or branched alkylthio group having 1 to 4 carbon atoms, or an aryl group having 6 to 12 carbon atoms,
wherein a ring R² is a heterocyclic ring containing a nitrogen atom,
wherein m is an integer of 1 to 5, n is an integer of 1 to 4, and
wherein the ring R² is a 3- to 6-membered ring.

16. The film formation apparatus of claim 15, further comprising:
a plasma generator configured to generate plasma,
wherein the controller is configured to cause the plasma generator to generate plasma of the OH-containing gas when supplying the OH-containing gas as the reaction gas to the substrate.
